(19) United States
(12) Patent Application Publication
(10) Pub. No.: US 2014/0197520 A1
(43) Pub. Date: Jul. 17, 2014

(54) RESISTOR AND RESISTOR FABRICATION FOR SEMICONDUCTOR DEVICES

(71) Applicant: QUALCOMM INCORPORATED, San Diego, CA (US)

(72) Inventors: Jihong Choi, San Diego, CA (US); John J. Zhu, San Diego, CA (US); Bin Yang, San Diego, CA (US); Giridhar Nallapati, San Diego, CA (US); PR Chidambaram, San Diego, CA (US)

(73) Assignee: QUALCOMM INCORPORATED, San Diego, CA (US)

(21) Appl. No.: 13/743,434

(22) Filed: Jan. 17, 2013

(51) Int. Cl. H01L 49/02; G06F 17/50

(52) U.S. Cl. CPC H01L 28/20; G06F 17/5068
USPC 257/536; 438/382; 716/110

(57) ABSTRACT

In a particular embodiment, a method includes removing a first portion of an optical planarization layer using a lithographic mask to expose a region of the optical planarization layer. A resistive layer is formed at least partially within the region. The method further includes removing at least a second portion of the optical planarization layer and at least a third portion of the resistive layer to form a resistor.

### I. FIELD

The present disclosure is generally related to semiconductor devices and more particularly to resistors and resistor fabrication for semiconductor devices.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

Electronic devices may include one or more integrated circuits that enable such computing capabilities and other functionalities. Fabricating an integrated circuit may include “front-end-of-line” (FEOL), “middle-of-line” (MOL), and “back-end-of-line” (BEOL) stages. Typically, the FEOL stage includes patterning devices upon a semiconductor substrate (e.g., forming source and drain regions of transistors of the integrated circuit). The MOL stage may include forming gate regions of the transistors and forming local interconnect layers (e.g., interconnect layers more proximate to the semiconductor substrate than other layers, such as metal interconnect layers) to connect the transistors. The BEOL stage may include forming metal interconnect layers to further connect the transistors and other devices of the integrated circuit.

### III. SUMMARY

In a conventional semiconductor device, to form a resistor, a high resistance structure may be formed in the semiconductor device and connectors may then be formed above the high resistance structure (e.g., in a local interconnect layer) to connect the high resistance structure to other components of the integrated circuit. However, because the high resistance structure may be of a small thickness, forming the connectors above the high resistance structure may inadvertently “punch through” the high resistance structure, which may significantly alter or degrade performance of the integrated circuit. Some conventional techniques attempt to prevent such “punch through” by altering thickness of the high resistance structure or by altering characteristics of how the connectors are formed above the high resistance structure. However, design or layout criteria may constrain how or whether the high resistance structure and the connectors can be altered. For example, the connectors may be formed according to the same process used to form other connector structures of the integrated circuit (e.g., vias that connect to the transistor source and drain regions). Which may reduce a “margin” for altering characteristics of the connectors (e.g., constrain how or if the process to form the connectors may be altered).

An integrated circuit fabrication technique in accordance with the present disclosure forms a resistor above a local interconnect layer that is connected to the resistor, reducing the likelihood of a connector “punching through” the resistor. The resistor may be formed according to a single-mask fabrication technique and may be formed during a middle-of-line (MOL) stage of fabricating the integrated circuit.

In a particular embodiment,a method includes removing a first portion of an optical planarization layer using a lithographic mask to expose a region of the optical planarization layer. A resistive layer is formed at least partially within the region. The method further includes removing at least a second portion of the optical planarization layer and at least a third portion of the resistive layer to form a resistor.

One particular advantage provided by at least one of the disclosed embodiments is that “punch through” associated with conventional systems may be avoided. For example, because a resistor is formed on a protective layer, punch through caused by forming the protective layer above the resistor and etching down to reach the resistor is avoided. Further, by utilizing a single-mask fabrication technique, costs and complexity are reduced as compared to multiple-mask fabrication techniques.

Other aspects, advantages, and features of the present disclosure will become apparent after review of the entire application, including the following sections:

### IV. BRIEF DESCRIPTION OF THE DRAWINGS

FIG. 1 is a diagram of a first illustrative diagram of a structure during t least one stage in a process of fabricating a semiconductor device;

FIG. 2 is a diagram of a second illustrative diagram of a structure during at least one stage in the process of fabricating a semiconductor device;

FIG. 3 is a diagram of a third illustrative diagram of a structure during at least one stage in the process of fabricating a semiconductor device;

FIG. 4 is a diagram of a fourth illustrative diagram of a structure during at least one stage in the process of fabricating a semiconductor device;

FIG. 5 is a diagram of a fifth illustrative diagram of a structure during at least one stage in the process of fabricating a semiconductor device;

FIG. 6 is a diagram of a sixth illustrative diagram of a structure during at least one stage in the process of fabricating a semiconductor device;

FIG. 7 is a flow chart of a particular illustrative embodiment of a method of forming a resistor according to a single-mask fabrication technique;

FIG. 8 is a block diagram of communication device including a, semiconductor device formed according to the method of FIG. 7; and

FIG. 9 is a data flow diagram of a particular illustrative embodiment of a manufacturing process to manufacture electronic devices that include a semiconductor device formed according to the method of FIG. 7.

### V. DETAILED DESCRIPTION

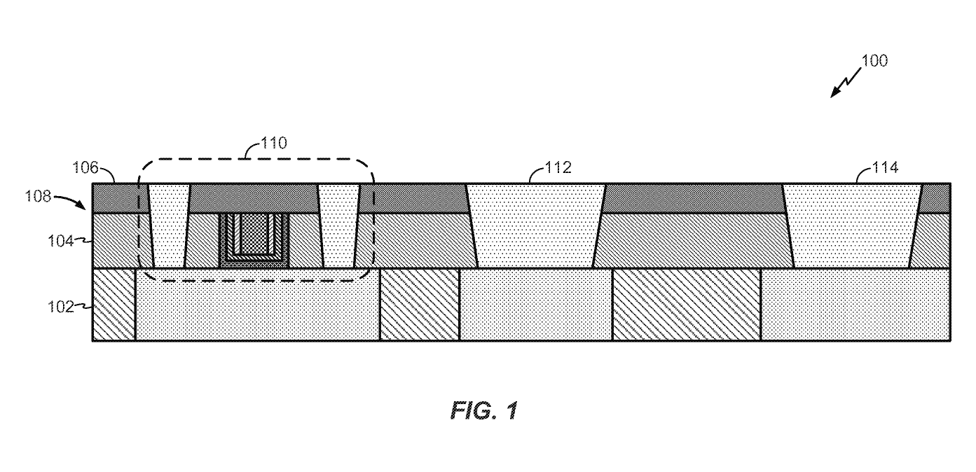

Referring to FIG. 1, a first illustrative diagram of a structure (e.g., a semiconductor structure) during at least one stage in a process of fabricating a semiconductor device (e.g., a process of fabricating an integrated circuit) is depicted and generally designated 100. In the particular embodiment of FIG. 1, an interconnect layer 108 is formed on a semiconductor substrate 102.

The interconnect layer 108 includes a dielectric layer 104 and a protective layer 106. The interconnect layer 108 may include one or more transistors or other devices. For example, FIG. 1 depicts that a transistor structure 110 may be formed within the interconnect layer 108. The interconnect layer 108 further includes a first connector 112 and a second connector 114. The interconnect layer 108 may be a local interconnect layer formed during a middle-of-line (MOL) fabrication stage of fabricating a semiconductor device (e.g., an integrated circuit). The interconnect layer 108 of FIG. 1 may be formed according to a chemical-mechanical polishing/planarization (CMP) fabrication technique.

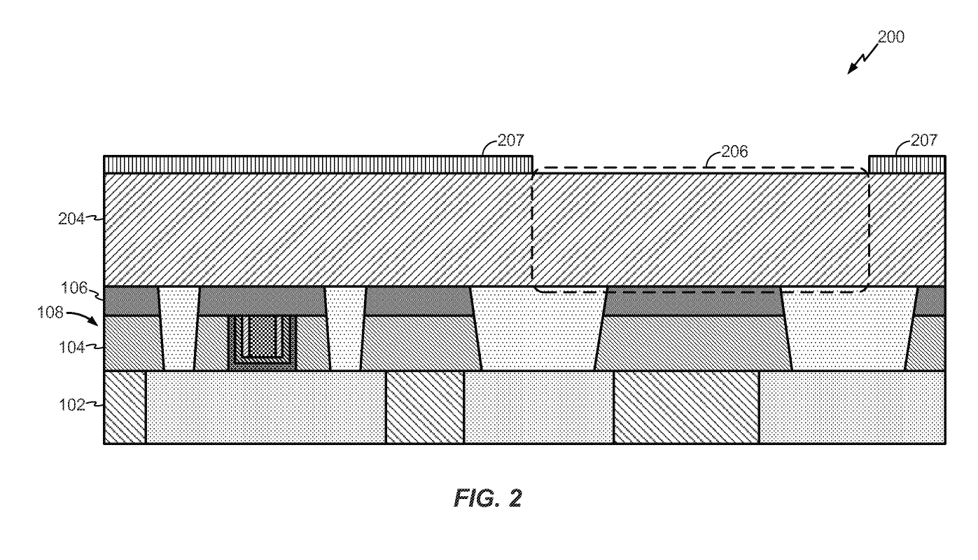

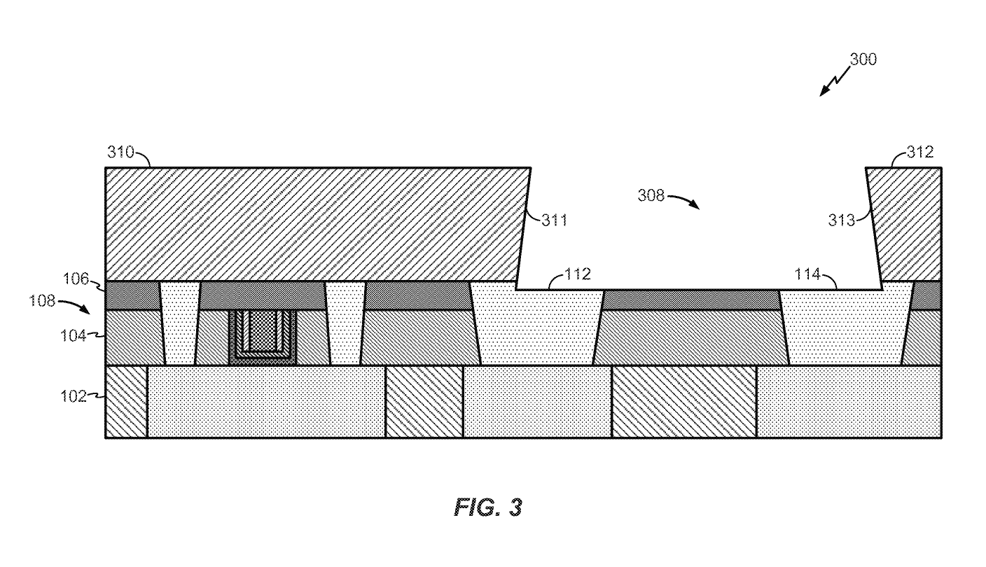

Referring to FIG. 2, a second illustrative diagram of a structure during at least one stage in the process of fabricating a semiconductor device is depicted and generally designated 200. In FIG. 2, a sacrificial layer (e.g., an optical planarization layer (OPL) 204, or another suitable structure) has been formed on the interconnect layer 108. For example, as shown in FIG. 2, the optical planarization layer 204 is formed on the protective layer 106 of the interconnect layer 108. As explained further with reference to FIG. 3, a portion of the optical planarization layer 204 may be removed to expose a region in which a resistor is to be formed. As an example, FIG. 2 depicts that a first portion 206 of the optical planarization layer 204 is to be removed to expose a region. FIG. 2 further depicts that a lithographic mask 207 has been formed on the optical planarization layer 204. The lithographic mask 207 defines a body area of a resistor to be formed in the region.

Referring to FIG. 3, a third illustrative diagram of a structure during at least one stage in the process of fabricating a semiconductor device is depicted and generally designated 300. As shown in FIG. 3, the first portion 206 of the optical planarization layer 204 described with reference to FIG. 2 has been removed (e.g., using the lithographic mask 207 of FIG. 2).

Removing the first portion 206 exposes a region 308. After removing the first portion 206, a second portion 310 of the optical planarization layer 204 and a third portion 312 of the optical planarization layer 204 remain. Further, as generally illustrated in FIG. 3, removing the first portion 206 of the optical planarization layer 204 to expose the region 308 may, intentionally or incidentally, remove other portions, such as portions of the connectors 112, 114, a portion of the protective layer 106, or a combination thereof. The region 308 is defined in part by sidewalk 311, 313 of the portions 310, 312.

FIG. 3 further depicts that the sidewalls 311, 313 of the portions 310, 312 may have a “negative” sidewall angle. That is, the sidewalls 311, 313 may not be precisely perpendicular relative to the semiconductor substrate 102. The “negative” sidewall angle of the sidewalls 311, 313 may be created by an etch process, such as an etch process used to expose the region 308, a cleaning process, or a combination thereof.

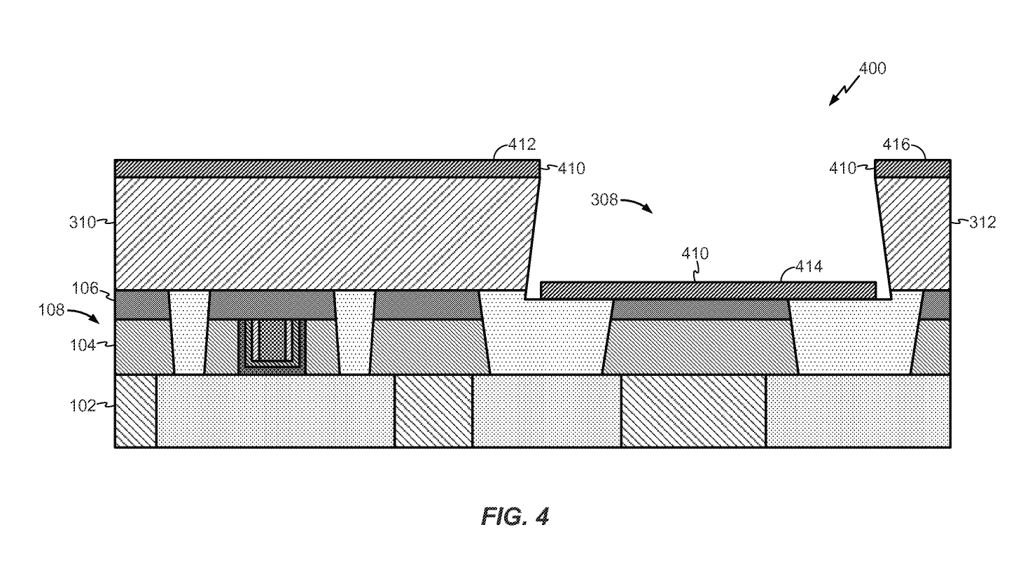

Referring to FIG. 4, a fourth illustrative diagram of a structure during at least one stage in the process of fabricating a semiconductor device is depicted and generally designated 400. In FIG. 4, a resistive layer 410 (e.g., a metal layer having a resistive material, such as a resistor body material, that causes the metal layer to have a high resistance) has been formed. The resistive layer 410 may include a thin metal film, such as a high-resistance thin metal film. For example, the resistive layer 410 may include elemental cobalt (Co), elemental ruthenium (Ru), elemental tantalum (Ta), elemental titanium (Ti), elemental tungsten (W), alloys thereof, bismuth-cobalt alloy, cobalt phosphide, titanium nitride (TiN), one or more tungsten silicides (WSiₓ), tantalum nitride (TaN), or a combination thereof.

In the example of FIG. 4, the resistive layer 410 includes a first portion 412, a second portion (i.e., the resistor 414), and a third portion 416. As shown in FIG. 4, the resistor 414 of the resistive layer 410 is formed within the region 308 and on the interconnect layer 108. The resistive layer 410 may be formed according to a physical vapor deposition (PVD) fabrication technique, a chemical vapor deposition (CVD) fabrication technique, a plasma-enhanced chemical vapor deposition (PECVD) fabrication technique, or a combination thereof.

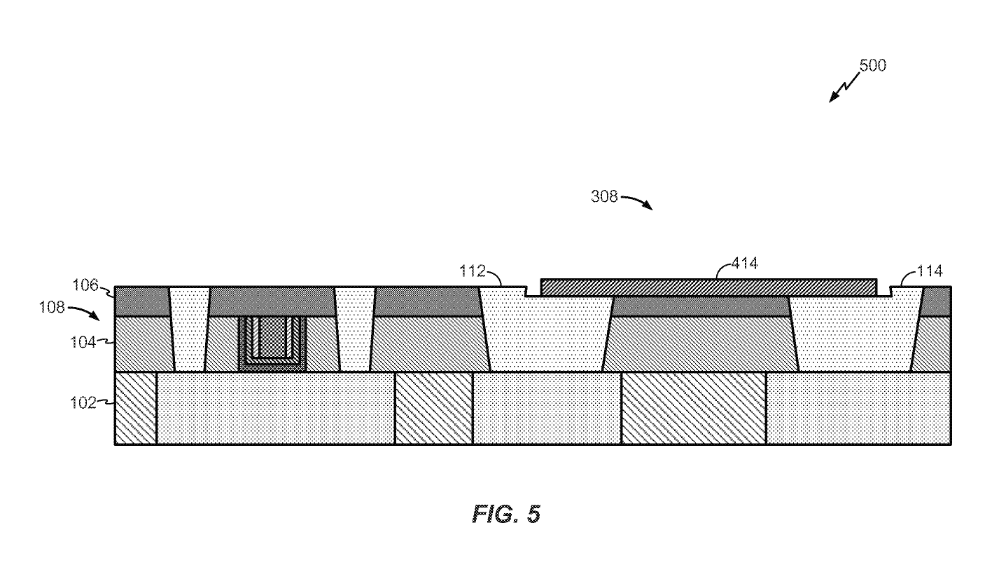

Referring to FIG. 5, a fifth illustrative diagram of a structure during at least one stage in the process of fabricating a semiconductor device is depicted and generally designated 500. In FIG. 5, the second portion 310, the third portion 312, the first portion 412, and the third portion 416 have been removed, leaving a portion of the resistive layer 410 (i.e., the resistor 414). Any of the second portion 310, the third portion 312, the first portion 412, and the third portion 416 may be removed using a lift-off fabrication technique, such as a metal lift-off fabrication technique, a wet etch/clean technique, or a combination thereof.

The resistor 414 may be formed on the interconnect layer 108. For example, as shown in FIG. 5, the resistor 414 is formed generally within the region 308 and is connected to the first connector 112 and to the second connector 114. In a particular illustrative embodiment, the resistor 414 is a high resistance resistor, such as a high resistance resistor having a sheet resistance of between 400 to 700 ohms. The resistor 414 of FIG. 5 may be of a “direct” metal-to-metal connection configuration (i.e., the resistor 411 may be directly connected to metal of the connectors 112, 114).

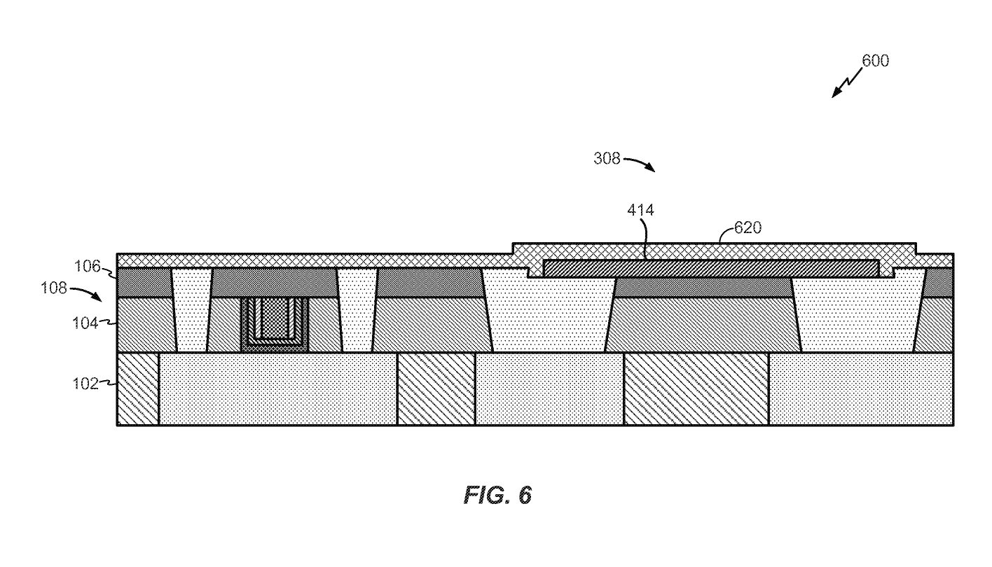

Referring to FIG. 6, a sixth illustrative diagram of a structure during at least one stage in the process of fabricating a semiconductor device is depicted and generally designated 600. In FIG. 6, a capping layer 620 has been deposited. As depicted in FIG. 6, the capping layer 620 may be formed on the resistor 414. In addition, and as depicted in FIG. 6, the capping layer 620 may have at least a portion formed on the interconnect layer 108 (e.g., on the protective layer 106). The capping layer 620 may electrically isolate the resistor 414 from other components of the structure 600 and may prevent other components above the resistor 414 from “punching through” the resistor 414. The resistor 414 may be coupled to other components of the structure 600 via the connectors 112, 114.

It will be appreciated that the process of FIGS. 1-6 describes a single-mask fabrication technique for forming resistors (e.g., the resistor 414). For example, because a single lithographic mask (i.e. the lithographic mask 207) is used in connection with the process of FIGS. 1-6 to form the resistor 414, costs and complexity are reduced as compared to multiple-mask fabrication techniques. In a particular embodiment, because the second portion 310, the third portion 312, the first portion 412, and the third portion 416 are removed using a lift-off fabrication technique, a single lithographic mask (i.e., the lithographic mask 207) may be utilized to form the resistor 414.

Further, by forming the resistor 414 above, rather than below, the protective layer 106, there is no need to etch through the protective layer to reach the resistor 414, thereby avoiding “punch through” of the resistor 414, which accordingly may relax design restraints (e.g., a minimum thickness of the resistor 414 and/or precise etch control to prevent over-etching) associated with the resistor 414. Accordingly, a process margin associated with the process of FIGS. 1-6 may be increased. Further, in at least some applications, because the resistor 414 can be made thinner without punch-through, the resistor 414 may be associated with a larger resistance target window (i.e., may be associated with a higher resistance as compared to conventional systems). For example, by avoiding etching down to reach the resistor 414, use of “etch stop” material may be avoided, which may enable the resistor 414 to have increased resistance.

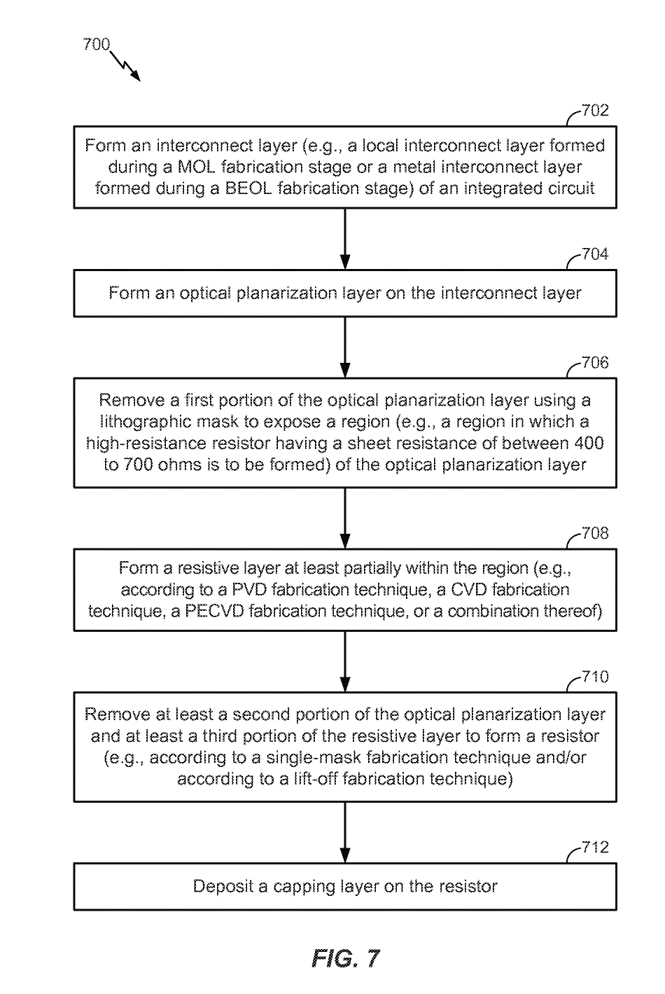

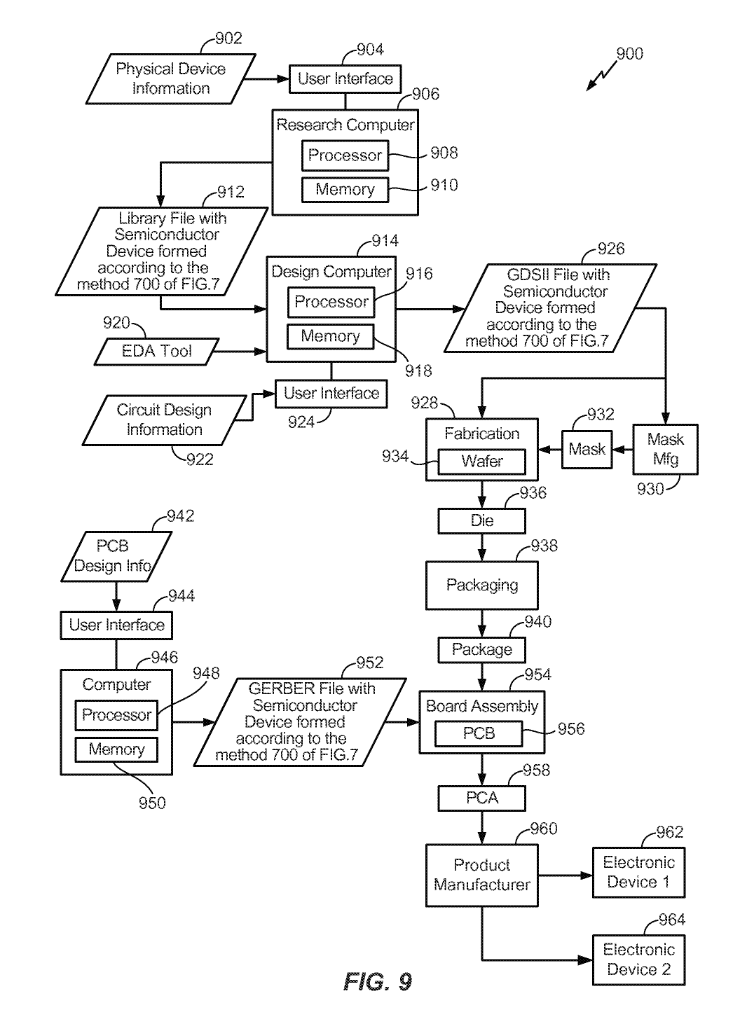

Referring to FIG. 7, a flow chart of a particular illustrative embodiment of a method of forming a resistor according to a single-mask fabrication technique is depicted and generally designated 700. One or more operations of the method 700 may be initiated by a processor integrated into an electronic device, as described further with reference to FIG. 9.

The method 700 includes forming an interconnect layer of an integrated circuit, at 702. The interconnect layer may be the interconnect layer 108 and may be a local interconnect layer formed during a middle-of-line (MOL) fabrication stage of fabricating the integrated circuit. According to at least one alternate embodiment, the interconnect layer may be a metal interconnect layer formed during a back-end-of-line (BEOL) fabrication stage of fabricating the integrated circuit

At 704, an optical planarization layer is formed on the interconnect layer. The optical planarization layer may be the optical planarization layer 204. At 706, a first portion (e.g., the first portion 206) of the optical planarization layer may be removed using a lithographic mask (e.g., the lithographic mask 207) to expose a region (e.g., the region 308) of the optical planarization layer. The region may be a region in which a resistor, such as a high-resistance resistor having a sheet resistance of between 400 to 700 ohms, is to be formed.

At 708, a resistive layer (e.g., the resistive layer 410) is formed at least partially within the region. For example, as described with reference to FIG. 4, the resistive layer 410 includes the resistor 414 formed within the region 308. The resistive layer may be formed according to a physical vapor deposition (PVD) fabrication technique, a chemical vapor deposition (CVD) fabrication technique, a plasma-enhanced chemical vapor deposition (PECVD) fabrication technique, or a combination thereof.

At 710, at least a second portion of the optical planarization layer (e.g., the second portion 310, third portion 312, or a combination thereof) and at least a third portion of the resistive layer (e.g., the first portion 412, the third portion 416, or a combination thereof) are removed to form a resistor (e.g., the resistor 414). The second portion of the optical planarization layer and the third portion of the resistive layer may be removed according to a lift-off fabrication technique and without utilizing a lithographic mask. Accordingly, the resistor described with reference to FIG. 7 is formed according to a single-mask technique. The method 700 may further include depositing a capping layer (e.g., the capping layer 620) on the resistor, at 712.

One or more of the operations described with reference to the method 700 of FIG. 7 may be initiated by a field-programmable gate array (FPGA) device, an application-specific integrated circuit (ASIC), a processing unit such as a central processing unit (CPU), a digital signal processor (DSP), a controller, another hardware device, a firmware device, or any combination thereof. As an example, the method 700 of FIG. 7 can be initiated by a processor that executes instructions stored at a memory (e.g., a non-transitory computer-readable medium) integrated within equipment of a semiconductor fabrication plant (e.g., a “fab”), as described further with reference to FIG. 9.

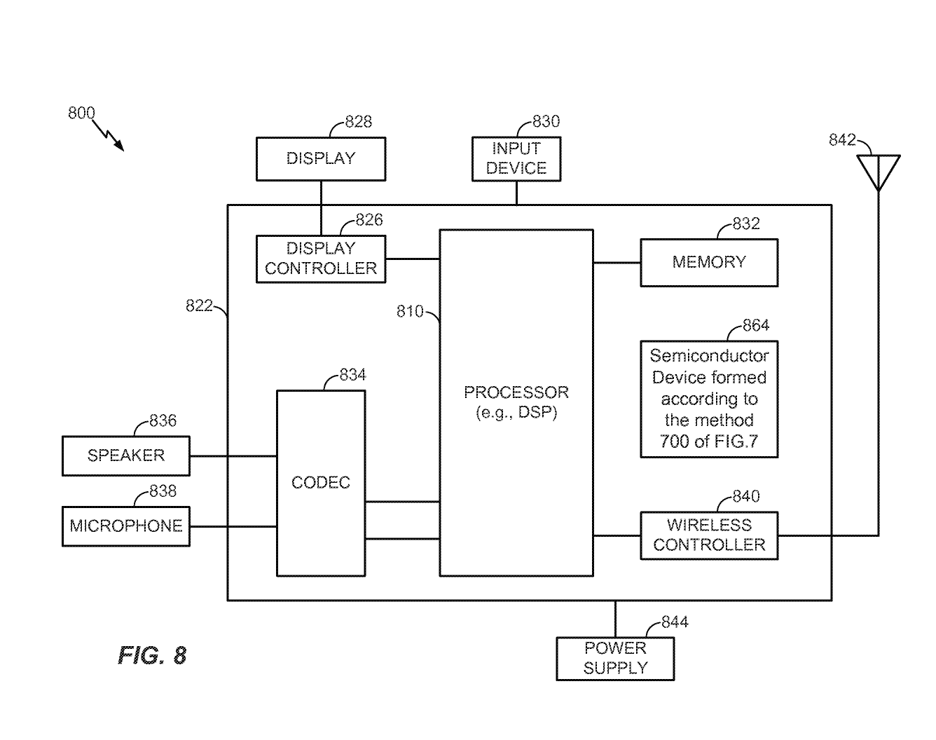

Referring to FIG. 8, a block diagram of a particular illustrative embodiment of a mobile device is depicted and generally designated 800. The mobile device 800 includes at least one semiconductor device formed according to the method 700 of FIG. 7. For example, the mobile device 800 may include a processor 810, such as a digital signal processor (DSP). The processor 810 may be coupled to a memory 832 (e.g., a non-transitory computer-readable medium) that stores instructions executable by the processor 810.

FIG. 8 also shows a display controller 826 that is coupled to the processor 810 and to a display 828. A coder/decoder (CODEC) 834 can also be coupled to the processor 810. A speaker 836 and a microphone 838 can be coupled to the CODEC 834. FIG. 8 also indicates that a wireless controller 840 can be coupled to the processor 810 and to a wireless antenna 842.

In a particular embodiment, the processor 810, the display controller $26, the memory 832, the CODEC 834, and the wireless controller 840 are included in a system-in-package or system-on-chip device 822. An input device 830 and a power supply 844 may be coupled to the system-on-chip device 822. Moreover, in a particular embodiment, as illustrated in FIG. 8, the display 828, the input device 830, the speaker 836, the microphone 838, the wireless antenna 842, and the power supply 844 are external to the system-on-chip device 822. However, each of the display 828, the input device 830, the speaker 836, the microphone 838, the wireless antenna 842, and the power supply 844 can be coupled to a component of the system-on-chip device 822, such as an interface or a controller. FIG. 8 also depicts that the system-on-chip device 822 may include a semiconductor device 864 formed according to the method 700 of FIG. 7. According to various embodiments, the semiconductor device 864 may be coupled to (or integrated within) one or more of the components of the mobile device 800, depending on the particular application.

The foregoing disclosed devices and functionalities may be designed and configured into computer files (e.g., RTL, GDSII, GERBER, etc.) stored on computer-readable media. Some or all such files may be provided to fabrication handlers to fabricate devices based on such files. Resulting products include semiconductor wafers that are then cut into semiconductor dies and packaged into semiconductor chips. The semiconductor chips are then employed in electronic devices. FIG. 9 depicts a particular illustrative embodiment of an electronic device manufacturing process 900.

Physical device information 902, is received at the manufacturing process 900, such as at a research computer 906. The physical device information 902 may include design information representing at least one physical property of a semiconductor device, such as a semiconductor device formed according to the method 700 of FIG. 7. For example, the physical device information 902 may include physical parameters, material characteristics, and structure information that is entered via a user interface 904 coupled to the research computer 906. The research computer 906 includes a processor 908, such as one or more processing cores, coupled to a computer-readable medium such as a memory 910. The memory 910 may store computer-readable instructions that are executable to cause the processor 908 to transform the physical device information 902 to comply with a file format and to generate a library file 912.

In a particular embodiment, the library file 912 includes at least one data file including the transformed design information. For example, the library file 912 may include a library of semiconductor devices, including a semiconductor device formed according to the method 700 of FIG. 7, provided for use with an electronic design automation (EDA) tool 920.

The library file 912 may be used in conjunction with the EDA tool 920 at a design computer 914 including a processor 916, such as one or more processing cores, coupled to a memory 918. The EDA tool 920 may be stored as processor executable instructions at the memory 918 to enable a user of the design computer 914 to design a circuit including the semiconductor device formed according to the method 700 of FIG. 7 using the library file 912. For example, a user of the design computer 914 may enter circuit design information 922 via a user interface 924 coupled to the design computer 914. The circuit design information 922 may include design information representing at least one physical property of a semiconductor device, such as a semiconductor device formed according to the method 700 of FIG. 7. To illustrate, the circuit design property may include identification of particular circuits and relationships to other elements in a circuit design, positioning information, feature size information, interconnection information, or other information representing a physical property of a semiconductor device.

The design computer 914 may be configured to transform the design information, including the circuit design information 922, to comply with a file format. To illustrate, the file formation may include a database binary file format representing planar geometric shapes, text labels, and other information about a circuit layout in a hierarchical format, such as a Graphic Data System (GDSII) file format. The design computer 914 may be configured to generate a data file including the transformed design information, such as a GDSII file 926 that includes information describing a semiconductor device formed according to the method 700 of FIG. 7, in addition to other circuits or information. To illustrate, the data file may include information corresponding to a system-on-chip (SOC) that includes a semiconductor device formed according to the method 700 of FIG. 7 and that also includes additional electronic circuits and components within the SOC.

The GDSII file 926 may be received at a fabrication process 928 to manufacture a semiconductor device according to the method 700 of FIG. 7 and according to transformed information in the GDSII file 926. For example, a device manufacture process may include providing the GDSII file 926 to a mask manufacturer 930 to create one or more masks, such as masks to be used with photolithography processing, illustrated in FIG. 9 as a representative mask 932. The mask 932 may be used during the fabrication process to generate one or more wafers 934, which may be tested and separated into dies, such as a representative die 936. The die 936 includes a circuit including a semiconductor device formed according to the method 700 of FIG. 7.

The die 936 may be provided to a packaging process 938 where the die 936 is incorporated into a representative package 940. For example, the package 940 may include the single die 936 or multiple dies, such as a system-in-package (SiP) arrangement. The package 940 may be configured to conform to one or more standards or specifications, such as Joint Electron Device Engineering Council (JEDEC) standards.

Information regarding the package 940 may be distributed to various product designers, such as via a component library stored at a computer 946. The computer 946 may include a processor 948, such as one or more processing cores, coupled to a memory 950. A printed circuit board (PCB) tool may be stored as processor executable instructions at the memory 950 to process PCB design information 942 received from a user of the computer 946 via a user interface 944. The PCB design information 942 may include physical positioning information of a packaged semiconductor device on a circuit board, the packaged semiconductor device corresponding to the package 940 including a semiconductor device formed according to the method 700 of FIG. 7.

The computer 946 may be configured to transform the PCB design information 942 to generate a data file, such as a GERBER file 952 with data that includes physical positioning information of a packaged semiconductor device on a circuit board, as well as layout of electrical connections such as traces and vias, where the packaged semiconductor device corresponds to the package 940 including a semiconductor device formed according to the method 700 of FIG. 7. In other embodiments, the data file generated by the transformed PCB design information may have a format other than a GERBER format.

The GERBER file 952 may be received at a board assembly process 954 and used to create PCBs, such as a representative PCB 956, manufactured in accordance with the design information stored within the GERBER file 952. For example, the GERBER file 952 may be uploaded to one or more machines to perform various steps of a PCB production process. The PCB 956 may be populated with electronic components including the package 940 to form a representative printed circuit assembly (PCA) 958.

The PCA 958 may be received at a product manufacture process 960 and integrated into one or more electronic devices, such as a first representative electronic device 962 and a second representative electronic device 964. As an illustrative, non-limiting example, the first representative electronic device 962, the second representative electronic device 964, or both, may be selected from the group of a set top box, a music player, a video player, an entertainment unit, a navigation device, a communications device, a personal digital assistant (PDA), a fixed location data unit, and a computer, into which a semiconductor device formed according to the method 700 of FIG. 7 is integrated. As another illustrative, non-limiting example, one or more of the electronic devices 962 and 964 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 9 illustrates remote units according to teachings of the disclosure, the disclosure is not limited to these illustrated units. Embodiments of the disclosure may be suitably employed in any device which includes active integrated circuitry including memory and on-chip circuitry.

A device that includes a semiconductor device formed according to the method 700 of FIG. 7 may be fabricated, processed, and incorporated into an electronic device, as described in the illustrative process 900. One or more aspects of the embodiments disclosed with respect to FIGS. 1-9 may be included at various processing stages, such as within the library file 912, the GDSII file 926, and the GERBER file 952, as well as stored at the memory 910 of the research computer 906, the memory 918 of the design computer 914, the memory 950 of the computer 946, the memory of one or more other computers or processors (not shown used at the various stages, such as at the board assembly process 954, and also incorporated into one or more other physical embodiments such as the mask 932, the die 936, the package 940, the PCA 958, other products such as prototype circuits or devices (not shown), or any combination thereof. Although various representative stages are depicted with reference to FIGS. 1-9, in other embodiments fewer stages may be used or additional stages may be included. Similarly, the process 900 of FIG. 9 may be performed by a single entity or by one or more entities performing various stages of the process 900.

In conjunction with the described embodiments, an apparatus is disclosed that includes a first semiconductor device (e.g., the semiconductor device 864) formed according to the method 700 of FIG. 7. The apparatus further includes means for electrically coupling the first semiconductor device to at least a second semiconductor device. In a particular embodiment, the means for electrically coupling the first semiconductor device to at least the second semiconductor device includes the PCB 956. The apparatus may be integrated within an electronic device, such as the first representative electronic device 962, the second representative electronic device 964, or a combination thereof.

In conjunction with the described embodiments, a non-transitory computer-readable medium stores instructions executable by a computer to initiate the method 700 of FIG. 7. In a particular embodiment, the non-transitory computer-readable medium includes a memory storing instructions executable by a processor to initiate fabrication of the wafer 934 according to the method 700 of FIG. 7. The processor and the memory may be integrated within an electronic device, such as equipment of a semiconductor fabrication plant.

Those of skill would further appreciate that the various illustrative blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A method comprising:
removing a first portion of an optical planarization layer using a lithographic mask to expose a region of the optical planarization layer;
forming a resistive layer at least partially within the region; and
removing at least a second portion of the optical planarization layer and at least a third portion of the resistive layer to form a resistor.

2. The method of claim 1, wherein the resistor is formed according to a single-mask fabrication technique, and wherein the second portion and the third portion are removed according to a lift-off fabrication technique.

3. The method of claim 1, further comprising:
forming an interconnect layer of an integrated circuit; and
forming the optical planarization layer on the interconnect layer.

4. The method of claim 3, wherein the interconnect layer is a local interconnect layer formed during a middle-of-line (MOL) fabrication stage of fabricating the integrated circuit.

5. The method of claim 4, wherein the interconnect layer is formed on a semiconductor substrate.

6. The method of claim 1, wherein the resistor is a high-resistance resistor having a shed resistance of between 400 to 700 ohms.

7. The method of claim 1, further comprising depositing a capping layer on the resistor.

8. The method of claim 1, wherein the resistive layer is formed according to a physical vapor deposition (PVD)fabrication technique, a chemical vapor deposition (CVD) fabrication technique, a plasma-enhanced chemical vapor deposition (PECVD) fabrication technique, or a combination thereof.

9. The method of claim 1, wherein removing the first portion of the optical planarization layer, forming the resistive layer, and removing the second portion and the third portion are initiated by a processor integrated into an electronic device.

10. An apparatus comprising:
a semiconductor device formed according to the method of claim 1.

11. The apparatus of claim 10, integrated in at least one semiconductor die.

12. The apparatus of claim 10, further comprising a device selected from the group of a set top box, a music player, a video player, an entertainment unit, a navigation device, a communications device, a personal digital assistant (PDA), a fixed location data unit, and a computer, into which the semiconductor device is integrated.

13. A method comprising:
a first step for removing a first portion of an optical planarization layer using a lithographic mask to expose a region;
a second step for forming a resistive layer at least partially within the region; and
a third step for removing at least a second portion of the optical planarization layer and at least a third portion of the resistive layer to form a resistor.

14. The method of claim 13, wherein the first step, the second step, and the third step are initiated by a processor integrated into an electronic device.

15. A method comprising:
receiving a data file including design information corresponding to a semiconductor device; and
fabricating the semiconductor device according to the design information, wherein the semiconductor device includes a resistor formed according to the method of claim 1.

16. The method of claim 15, wherein the data file has a GDSII format.

17. A method comprising:
receiving design information including physical positioning information of a packaged semiconductor device on a circuit board, the packaged semiconductor device including a semiconductor device that includes a resistor formed according to the method of claim 1; and
transforming the design information to generate a data file.

18. The method of claim 17, wherein the data file has a GERBER format.

19. A method comprising:
receiving a data file including design information including physical positioning information of a packaged semiconductor device on a circuit board; and
manufacturing the circuit board, the circuit board configured to receive the packaged semiconductor device according to the design information, wherein the packaged semiconductor device includes a semiconductor device that includes a resistor formed according to the method of claim 1.

20. The method of claim 19, wherein the data file has a GERBER format.

21. The method of claim 19, further comprising integrating the circuit board into a device selected from the group of a set top box, a music player, a video player, an entertainment unit, a navigation device, a communications device, a personal digital assistant (PDA), a fixed location data unit, and a computer.

22. A non-transitory computer-readable medium storing instructions executable by a computer to initiate the method of claim 1.

23. An apparatus comprising:
a first semiconductor device that includes a resistor formed according to the method of claim 1; and
means for electrically coupling the first semiconductor device to at least a second semiconductor device.

24. The apparatus of claim 23, wherein the means for electrically coupling the first semiconductor device to at least the second semiconductor device comprises a printed circuit hoard (PCB).
